(19) United States
(12) Patent Application Publication
(10) Pub. No.: US 2014/0159782 A1
(43) Pub. Date: Jun. 12, 2014

(54) Divide-By-Three Injection-Locked Frequency Divider

(71) Applicants: Michael Peter Kennedy, Ballincollig (IE); Malik Summair Ashgar, Popes Quay (IE); Muhammad Asfandyar Awan, Popes Quay (IE); Antonio Buonomo, Caserta (IT); Alessandro Lo Schiavo, Napoli (IT)

(72) Inventors: Michael Peter Kennedy, Ballincollig (IE); Malik Summair Ashgar, Popes Quay (IE); Muhammad Asfandyar Awan, Popes Quay (IE); Antonio Buonomo, Caserta (IT); Alessandro Lo Schiavo, Napoli (IT)

(21) Appl. No.: 14/100,322

(22) Filed: Dec. 9, 2013

Related U.S. Application Data
(60) Provisional application No. 61/734,931, filed on Dec. 7, 2012.

(51) Int. Cl. H03B 19/14

(52) U.S. Cl. CPC H03B 19/14
USPC 327/118

(57) ABSTRACT

At least one embodiment of the invention relates to an injection-locked frequency divider adapted to generate a signal at an output frequency from an input frequency over a large range of input frequencies, wherein said input frequency is either an even or an odd integer multiple of the output frequency.

This application claims the benefit of U.S. Provisional Patent Application Ser. No. 61/734,931, filed 7 Dec. 2012, the specification of which is hereby incorporated herein by reference.

### BACKGROUND OF THE INVENTION

1. Field of the Invention

Embodiments of the invention relate to an injection-locked frequency divider.

2. Description of the Related Art

Every wireless communication device uses a frequency synthesizer to set the frequency of the communication channel. The output frequency of an indirect frequency synthesizer is usually generated by phase locking the output frequency to a precise frequency reference. The phase-locked loop at the core of the frequency synthesizer contains a frequency divider.

This divider usually comprises two sections: a prescaler, which divides by a fixed number, and a variable modulus divider, which divides by a variable number. The prescaler operates at the output frequency and typically consumes a large amount of power.

The power consumption of the divider is an important consideration when it is integrated into a complete system, particularly in the case of portable communication devices. This invention has the potential to reduce the power consumption and size of the prescaler by replacing a digital divider by an analog divider.

The use of digital frequency dividers is constrained at high frequencies by their high power consumption, which increases rapidly with frequency. As an alternative, analog frequency dividers are realized for their lower power consumption and high speed and frequency capabilities. Frequency dividers can be realized using Common Mode Logic (CML), dynamic logic, Miller dividers and Injection Locked Frequency Dividers (ILFD). Compared to CML and Miller dividers, the power consumption of an ILFD does not increase significantly with frequency.

An ILFD is an electronic oscillator, which produces an output signal whose period (equivalently, zero-crossing rate) is rationally related to that of the input signal. When there is no injected input signal, the oscillator oscillates with a free-running frequency f₀. When an injection signal vᵢₙ is applied with a frequency fᵢₙ, then the output signal vₒᵤₜ oscillates with a frequency fₒᵤₜ. The ratio of fᵢₙ/fₒᵤₜ is called the rotation number, denoted by ρ. This locking behavior is due to the nonlinear phenomenon of synchronization, also known as entrainment or 1:ρ order injection locking. When ρ is an integer, the circuit is commonly called a divide-by-ρ ILFD.

The advantage of the ILFD is that it has the potential for low power operation because the relatively small perturbation by the input signal does not significantly affect the power consumption of the underlying oscillator. However, ILFDs have two major drawbacks. Firstly, they are poorly understood from a theoretical point of view, despite a long history of research and significant progress since the advent of computational nonlinear dynamics. Secondly, the ILFD is bandpass in nature, meaning that it divides correctly only over a small range of frequencies. This is related to the entrainment phenomenon; the oscillator locks to the perturbing input signal with the correct frequency division ratio p over the so-called Locking Range (LR).

In frequency synthesizers, it is common to divide a frequency by a fixed integer prior to dividing it by a variable number. Most ILFD architectures are capable of dividing by even integers (typically two or four). In many applications, it is required to divide by odd integers,

Circuit topologies that realize frequency division by even numbers, e.g.divide-by-2 prescalers, have been studied extensively in the literature. In order to avoid pulling in transceivers, there is a demand from radio systems architects for division by numbers other than two, and in particular, division by odd numbers. In recent years, frequency division by odd numbers, particularly divide-by-3, has received increasing attention.

In prior art, Jang et al. and Lee et al. use CMOS LC oscillator circuits with multiple inductors. These ILFDs, which are capable of dividing by three, incorporate auxiliary networks that contain inductors and therefore consume a large chip area when implemented in monolithic form. The increased area occupied by the inductors also increases the cost of the divider. Furthermore, the use of inductors increases the susceptibility to electromagnetic interference (EMI). Other papers in the art include:

M. Tiebout, “A CMOS direct injection-locked oscillator topology as high-frequency low-power frequency divider,” IEEE J. Solid-State Circuits, vol. 39, no. 7, pp. 1170-1174, July 2004.

S.-L. Jang and C.-F. Lee, “A wide locking range LC-tank injection locked frequency divider,” IEEE Microw. Wireless Compon. Lett., vol. 17, no. 8, pp. 613-615, August 2007.

S.-L. Jang, C.-F. Lee and W.-H. Yeh, “A divide-by-3 injection-locked frequency divider with single-ended input,” IEEE Microw. Wireless Compon. Lett, vol. 18, no. 2, pp. 142-144, February 2008.

I.-T. Lee, C.-H. Wang and S.-I. Liu. “Current-reused divide-by-3 injection-locked frequency divider in 65 nm CMOS,” Electronics Lett., vol. 47, no. 18. September 2011.

A. Buonomo, A. Lo Schiavo, M. A. Awan, M. S. Asghar and M. P. Kennedy, “A CMOS Injection-Locked Frequency Divider Optimized for Divide-by-Two and Divide-by-Three Operation.” IEEE Trans. Circuits Syst.-I, vol. 60, pp. 3126-3135, December 2013.

It is therefore an object of at least one embodiment of the invention to provide an electronic system, circuit, device and method to divide by odd integers without incurring the cost or EMI penalties associated with inductors in the injection network.

### BRIEF SUMMARY OF THE INVENTION

At least one embodiment of the invention provides, as set out in the appended claims, an injection-locked frequency divider circuit or device adapted to generate a signal at an output at an output frequency received from an input at an input frequency over a large range of input frequencies, wherein said input frequency is either an even or odd integer multiple of the output frequency.

At least one embodiment of invention provides a simpler circuit that is significantly smaller and less prone to electromagnetic interference than prior art divide-by-3 ILFDs. The auxiliary injection network in this ILFD uses no inductors, making it smaller and therefore simpler and cheaper to implement. It is also less susceptible to electromagnetic interference.

In one embodiment a path from the input to the output comprises a high-pass transfer function.

In one embodiment a capacitor is positioned between the input and output of the injection-locked frequency divider.

In one embodiment the injection-locked frequency divider comprises an LC oscillator adapted with tail injection.

In one embodiment the LC oscillator comprises an asymmetric oscillator core.

In one embodiment the asymmetric oscillator core comprises only NMOS or PMOS transistors.

In one embodiment there is provided two coupling capacitors connected such that the voltage across the tank is forced by the tail injection.

In one embodiment the injection-locked frequency divider comprises an LC oscillator adapted with direct injection.

In one embodiment there are provided a first and a second complementary transistor connected across a resonant circuit to provide a differential input signal.

In one embodiment the first complementary transistor comprises a first capacitor adapted to allow a synchronizing signal to be applied to one end of the resonant circuit.

In one embodiment the second complementary transistor comprises a second capacitor adapted to allow a synchronizing signal to be applied differentially across the resonant circuit.

is In one embodiment of the invention, the ILFD comprises a CMOS LC oscillator core. The injected signal is applied to a transistor that is connected directly across the resonant circuit; this is called single-ended direct injection. A capacitive path is provided between the input and one side of the resonant LC tank.

In another embodiment of the invention, the ILFD comprises a CMOS LC oscillator core. The injected signal is applied to two complementary transistors that are connected directly across the resonant circuit; this is called differential direct injection. Two capacitive paths are provided between the two ends of the differential input and the two ends of the resonant LC tank.

In particular, at least one embodiment of the invention relates to an injection-locked frequency divider with direct injection and an auxiliary connection between the input and output that facilitates division by odd integers over a wide range of input frequencies.

The solution of at least one embodiment of the invention provides a low power advantage (compared to a digital divider) of an ILFD and uses just one inductor, making the frequency divider smaller and less prone to electromagnetic interference.

There is also provided a computer program comprising program instructions for causing a computer program to carry out the above method which may be embodied on a record medium, carrier signal or read-only memory.

### BRIEF DESCRIPTION OF THE DRAWINGS

Embodiments of invention will be more clearly understood from the following description of an embodiment thereof, given by way of example only, with reference to the accompanying drawings, in which:

FIG. 1 illustrates a block diagram of a frequency synthesizer;

FIG. 2a illustrates an implementation of an asymmetric injection-locked frequency divider with tail injection;

FIG. 2b illustrates an implementation of a symmetric injection-locked frequency divider with direct injection;

FIG. 3 illustrates measured locking regions for an implementation of a symmetric injection-locked frequency divider with direct injection;

FIG. 4 illustrates a block diagram of an injection-locked frequency divider according to one embodiment of the invention;

FIG. 5 illustrates simulated divide-by-two and divide-by-three locking regions for one embodiment of the invention;

FIG. 6 illustrates a block diagram of an injection-locked frequency divider according to a second embodiment of the invention;

FIG. 7 illustrates measured divide-by-two and divide-by-three locking regions for one embodiment of the invention;

FIG. 8 illustrates the equivalent circuit and subcircuits; and

FIG. 9 illustrates the injection locking mechanism that facilitates divide-by-three over a wide locking range.

### DETAILED DESCRIPTION OF THE INVENTION

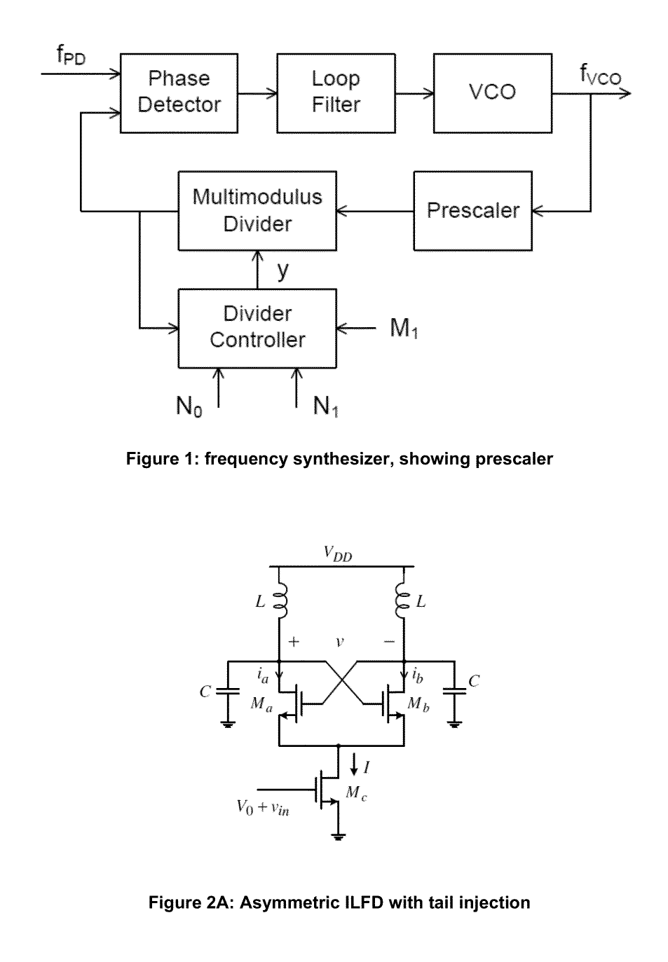

FIG. 1 shows a fractional-N frequency synthesizer. The output frequency divided by an integer divider that comprises a fixed divider (prescaler) and a variable divider. The prescaler can be implemented as an injection-locked frequency divider (ILFD).

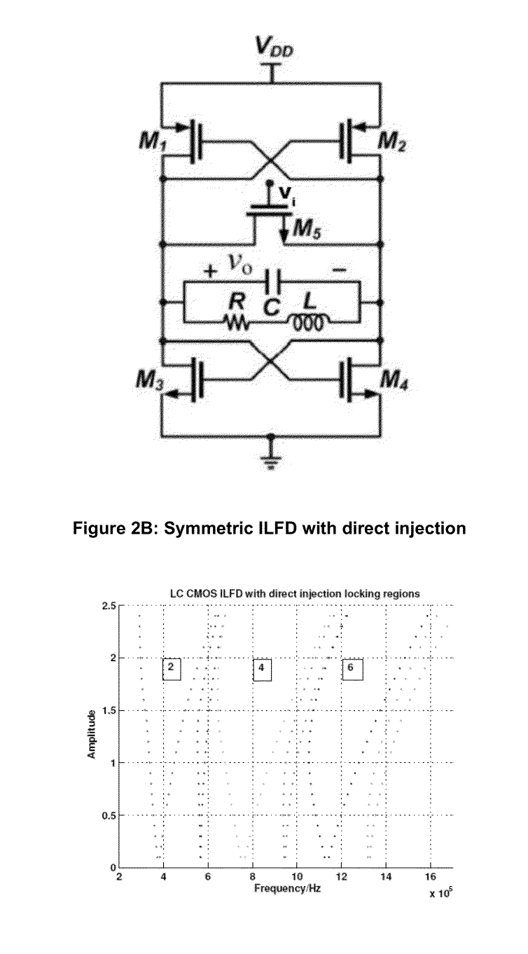

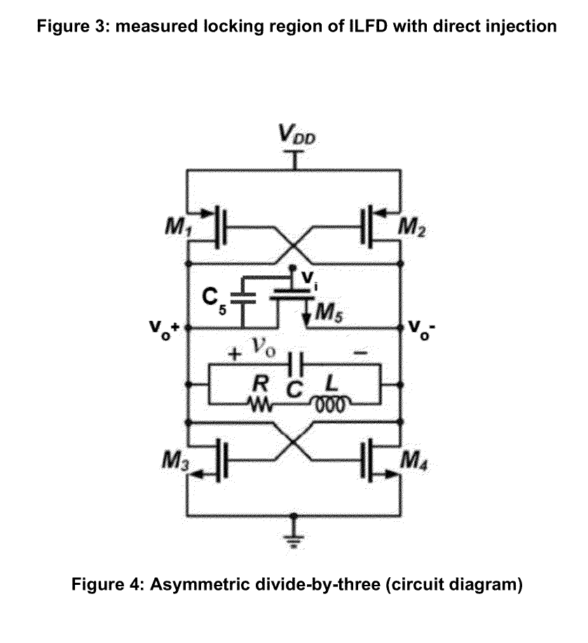

In the ILFD, shown in FIGS. 2a and 2b, the so-called “Arnold tongue” locking regions over which the output frequency is an integer submultiple of the input frequency are wider for even integers and narrower for odd integers. This is illustrated for the symmetric direct injection case (FIG. 2b) in FIG. 3.

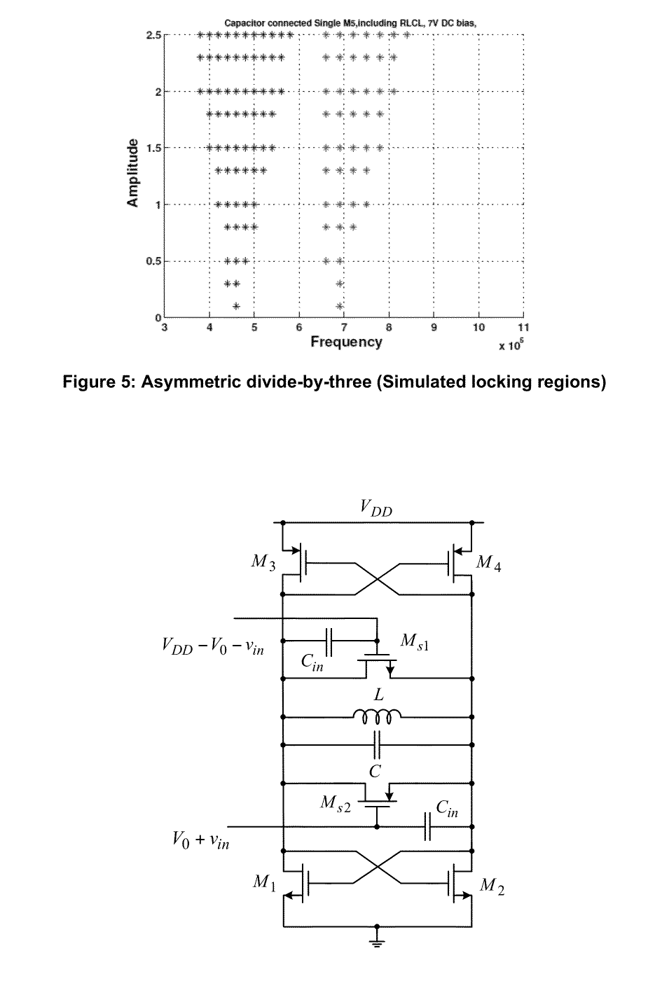

One embodiment of the invention is shown in FIG. 4 illustrating a Divide-By-Three Injection-Locked Frequency Divider circuit comprising a single-ended input and a differential output. The frequency divider comprises an asymmetric highpass connection between the input and the output consisting of a single capacitor C₅ connected to the direct injection transistor M₅. The simulated width of the divide-by-3 locking region is comparable to that of the divide-by-2 region. These comparison results are illustrated in FIG. 5.

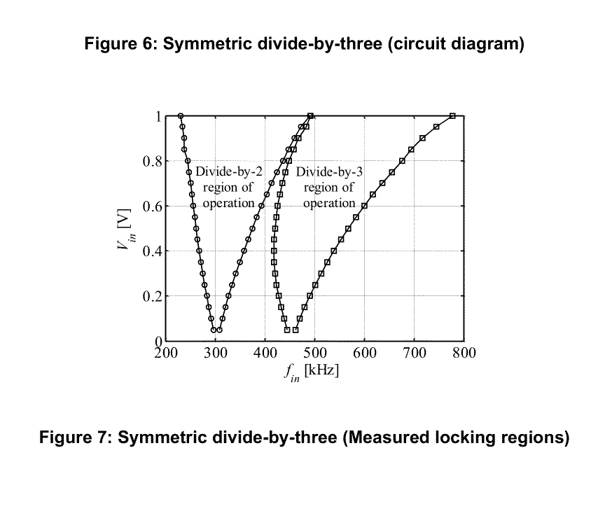

A second embodiment of the Divide-By-Three Injection-Locked Frequency Divider, as shown in FIG. 6, comprises a differential input and a differential output. The frequency divider comprises a basic symmetric LC differential oscillator with complementary topology, and an injection circuit by which the synchronization signal Vᵢₙ is injected directly into the oscillator. It contains a symmetric highpass connection between the input and the output. The injection takes place via two complementary MOS switches, Mₛ₁ and Mₛ₂, driven by the signal vᵢₙ, and two coupling capacitors Cᵢₙ which allow the synchronizing signal to be applied differentially across the drain nodes.

The measured width of the divide-by-3 locking region is comparable to that of the divide-by-2 region. This is illustrated in FIG. 7.

To illustrate the principle of operation of the divider, and develop its behavioral model under the action of the synchronization signal Vᵢₙ, the signal is assumed to be purely sinusoidal with angular frequency ωᵢₙ and amplitude Vin, that is, vᵢₙ=Vᵢₙ COS(ωᵢₙt).

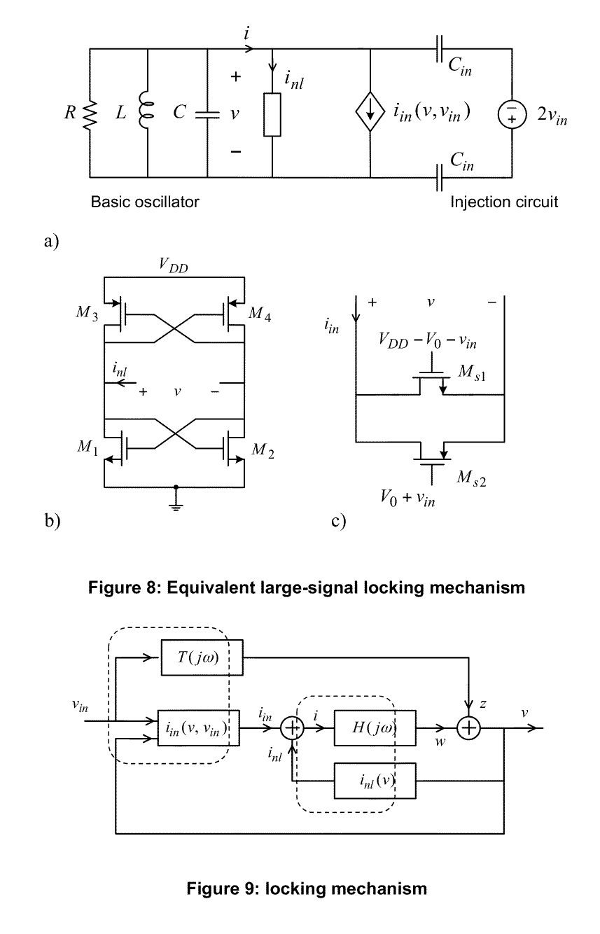

FIG. 8(a) shows the large-signal equivalent circuit of the divider. The basic oscillator is represented by the parallel connection of the LC-tank, whose losses are represented by an equivalent parallel resistance R, and a nonlinear two-terminal resistor with a driving-point characteristic iₙ₁(v), which represents the current-voltage relationship of the locally active part of the oscillator.

FIG. 8(b) shows the locally active part of the oscillator in the case of the symmetric complementary CMOS transistor pairs in FIG. 6.

The injection circuit comprises a controlled current source, which represents the nonlinear two-terminal resistor, shown in FIG. 8(c), formed by the two MOS switches and a voltage source 2vᵢₙ that is connected to the LC-tank via two coupling capacitors Cᵢₙ. Note that the port current iᵢₙ of the two-terminal resistor in FIG. 8(c) depends not only on the synchronization signal vᵢₙ but also on the differential voltage v; therefore, it is represented by a function iᵢₙ(v, vᵢₙ).

Note that two independent injection techniques are used in the circuit in FIG. 8(a), namely injecting a current into the tank through the switches and forcing a voltage across the tank through the capacitors.

To understand intuitively how the circuit operates as a divider, it is useful to represent the equivalent circuit in FIG. 8(a) by the block-diagram in FIG. 9. Here, T(jω) denotes the high-pass transfer function that transforms the injection signal vᵢₙ into the differential voltage z of the linear circuit obtained with iₙ₁=0, that is,

$$T ( jω ) = \frac{z}{{v}_{in}} = \frac{{C}_{in}}{{C}_{e}} \frac{{( jω )}^{2}}{{( jω )}^{2} + \frac{1}{{RC}_{e}} jω + \frac{1}{{LC}_{e}}}$$

H(jω) is the pass-band transfer function of the LC-tank, that is

$$H ( jω ) = \frac{w}{i} = - \frac{1}{{C}_{e}} \frac{jω}{{( jω )}^{2} + \frac{1}{{RC}_{e}} jω + \frac{1}{{LC}_{e}}} .$$

The block diagram shown in FIG. 9 illustrates how the circuit can operate in both divide-by-2 and divide-by-3 modes. In particular, the block iᵢₙ(v, vᵢₙ), corresponding to the injection circuit, allows one to obtain divide-by-2 operation, while the block T(jω) facilitates divide-by-3 operation.

In another embodiment of the invention, the asymmetric oscillator core comprises only NMOS or PMOS transistors, such as shown in FIG. 2a. The voltage across the tank is forced by the injection network in FIG. 8c with two coupling capacitors is connected between the gate of Mₛ₁ and v⁺ and between the gate of Mₛ₂ and v⁻, respectively.

The embodiments in the invention described with reference to the drawings comprise a computer apparatus and/or processes performed in a computer apparatus. However, embodiments of the invention also extend to computer programs, particularly computer programs stored on or in a carrier adapted to bring embodiments of the invention into practice. The program may be in the form of source code, object code, or a code intermediate source and object code, such as in partially compiled form or in any other form suitable for use in the implementation of the method according to at least one embodiment of the invention. The carrier may comprise a storage medium such as ROM, e.g. CD ROM, or magnetic recording medium, e.g. a floppy disk or hard disk. The carrier may be an electrical or optical signal, which may be transmitted via an electrical or an optical cable or by radio or other means.

In the specification the terms “comprise, comprises, comprised and comprising” or any variation thereof and the terms include, includes, included and including” or any variation thereof are considered to be totally interchangeable and they should all be afforded the widest possible interpretation and vice versa.

At least one embodiment of the invention is not limited to the embodiments hereinbefore described but may be varied in both construction and detail.

1. An injection-locked frequency divider circuit adapted to generate a signal at an output at an output frequency received from an input at an input frequency over a large range of input frequencies, wherein said input frequency is either an odd or even integer multiple of the output frequency.

2. An injection-locked frequency divider as claimed in claim 1 wherein a path from the input to the output comprises a high-pass transfer function.

3. An injection-locked frequency divider as claimed in claim 1 comprising a capacitor positioned between the input and output.

4. An injection-locked frequency divider as claimed in claim 1 comprising an LC is oscillator and adapted with direct injection.

5. An injection-locked frequency divider as claimed in claim 4 comprising a symmetric oscillator core and a first and second complementary transistor connected across a resonant circuit to provide a differential input signal.

6. An injection-locked frequency divider as claimed in claim 5 wherein the first complementary transistor comprises a first capacitor adapted to allow a synchronizing signal to be applied to one end of the resonant circuit.

7. An injection-locked frequency divider as claimed in claim 5 wherein the second complementary transistor comprises a first and a second capacitor adapted to allow a synchronizing signal to be applied differentially to the resonant circuit.

8. An injection-locked frequency divider as claimed in claim 1 comprising an LC oscillator and adapted with tail injection.

9. An injection-locked frequency divider as claimed in claim 8 wherein the LC oscillator comprises an asymmetric oscillator core.

10. An injection-locked frequency divider as claimed in claim 8 wherein the LC oscillator comprises an asymmetric oscillator core and the asymmetric oscillator core comprises only NMOS or PMOS transistors.

11. An injection-locked frequency divider as claimed in claims 8 comprising two coupling capacitors connected such that the voltage across the tank is forced by the tail injection.
